(19) United States
(12) Patent Application Publication
(10) Pub. No.: US 2023/0197895 A1
(43) Pub. Date: Jun. 22, 2023

(54) LIGHT EMITTING DIODE

(71) Applicant: ANHUI SANAN OPTOELECTRONICS CO., LTD., Wuhu (CN)

(72) Inventors: Zhibo XU, Wuhu (CN); Zhihua ZHANG, Wuhu (CN); Mingbin MA, Wuhu (CN); Cheng-Hung LEE, Wuhu (CN); Chan-Chan LIN, Wuhu (CN); Chia-Hao CHANG, Xiamen (CN)

(21) Appl. No.: 18/174,009

(22) Filed: Feb. 24, 2023

Related U.S. Application Data
(63) Continuation-in-part of application No. PCT/CN2020/115032, filed on Sep. 14, 2020.

(51) Int. Cl. H01L 33/12; H01L 33/00; H01L 33/06; H01L 33/24; H01L 33/32

(52) U.S. Cl. CPC H01L 33/12; H01L 33/007; H01L 33/06; H01L 33/24; H01L 33/32

(57) ABSTRACT

A light emitting diode includes a first conductivity-type semiconductor layer, a second conductivity-type semiconductor layer, a light emitting layer, and a stress relief layer. The second conductivity-type semiconductor layer has a conductivity type opposite to that of the first conductivity-type semiconductor layer. The light emitting layer is disposed between the first conductivity-type semiconductor layer and the second conductivity-type semiconductor layer. The stress relief layer is disposed between the first conductivity-type semiconductor layer and the light emitting layer, and includes well layers and barrier layers stacked alternately. The stress relief layer further includes at least one blocking zone in at least one of the well layers. The at least one blocking zone has an energy gap greater than an energy gap of the at least one of the well layers. A method for manufacturing the light emitting diode is also disclosed.

### CROSS-REFERENCE TO RELATED APPLICATION

This application is a bypass continuation-in-part (CIP) application of PCT International Application No. PCT/CN2020/115032, filed on Sep. 14, 2020. The entire content of the International Patent Application is incorporated herein by reference.

### FIELD

The disclosure relates to a semiconductor device and a method for manufacturing the same, and more particularly to a light emitting diode having a stress relief layer and a method for manufacturing the same. By providing blocking zone(s) in well layer(s) of the stress relief layer, non-radiative recombination of carriers at dislocations, due to lateral movement of the carriers, may be alleviated or eliminated, thereby improving internal quantum efficiency of the light emitting diode.

### BACKGROUND

Referring to FIG. 1, for manufacturing a light emitting diode, a metal organic chemical vapor deposition (MOCVD) technique is conventionally adopted for sequentially growing an n-type semiconductor layer 20′, a stress relief layer 30′, a light emitting layer 40′, and a p-type semiconductor layer 50′ on a heterogeneous substrate 10′. Owing to a severe lattice mismatch between the heterogeneous substrate 10′ (e.g., a sapphire substrate) and the n-type semiconductor layer 20′ (e.g., an n-type GaN layer), a large number of dislocations D′ are formed during an epitaxial growth process. As a result, non-radiative recombination of carriers (e.g., electrons and holes) occurs at sites of these dislocations D′, causing a reduction of light emission efficiency of the active layer 40′, which explains mainly the reason for a low internal quantum efficiency of the light emitting diode.

Therefore, there is an urgent need at present to reduce the occurrence of non-radiative recombination of carriers.

### SUMMARY

Therefore, an object of the disclosure is to provide a light emitting diode (LED) and a method for manufacturing the same that can alleviate at least one of the drawbacks of the prior art.

According to a first aspect of the disclosure, the LED includes a first conductivity-type semiconductor layer, a second conductivity-type semiconductor layer, a light emitting layer, and a stress relief layer. The second conductivity-type semiconductor layer has a conductivity type opposite to that of the first conductivity-type semiconductor layer. The light emitting layer is disposed between the first conductivity-type semiconductor layer and the second conductivity-type semiconductor layer. The stress relief layer is disposed between the first conductivity-type semiconductor layer and the light emitting layer, and includes well layers and barrier layers stacked alternately. The stress relief layer further includes at least one blocking zone distributed in at least one of the well layers. The at least one blocking zone has an energy gap greater than an energy gap of the at least one of the well layers.

According to a second aspect of the disclosure, the method includes the steps of:
(a) providing a substrate;
(b) depositing a first conductivity-type semiconductor layer on the substrate;
(c) depositing a stress relief layer on the first conductivity-type semiconductor layer, the stress relief layer including well layers and barrier layers stacked alternately;
(d) depositing a light emitting layer on the stress relief layer; and
(e) depositing a second conductivity-type semiconductor layer on the light emitting layer,
   wherein the stress relief layer further includes at least one blocking zone formed in at least one of the well layers, an energy gap of the at least one blocking zone being greater than an energy gap of the at least one well layers.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a cross-sectional schematic view illustrating a conventional light emitting diode (LED).

FIG. 2 is a cross-sectional view illustrating an LED according to an embodiment of the disclosure.

FIG. 3 is a top schematic view illustrating a well layer of the LED according to the embodiment of the disclosure.

FIG. 4 is a cross-sectional transmission electron microscope (TEM) image illustrating a stress relief layer of the LED according to the embodiment of the disclosure.

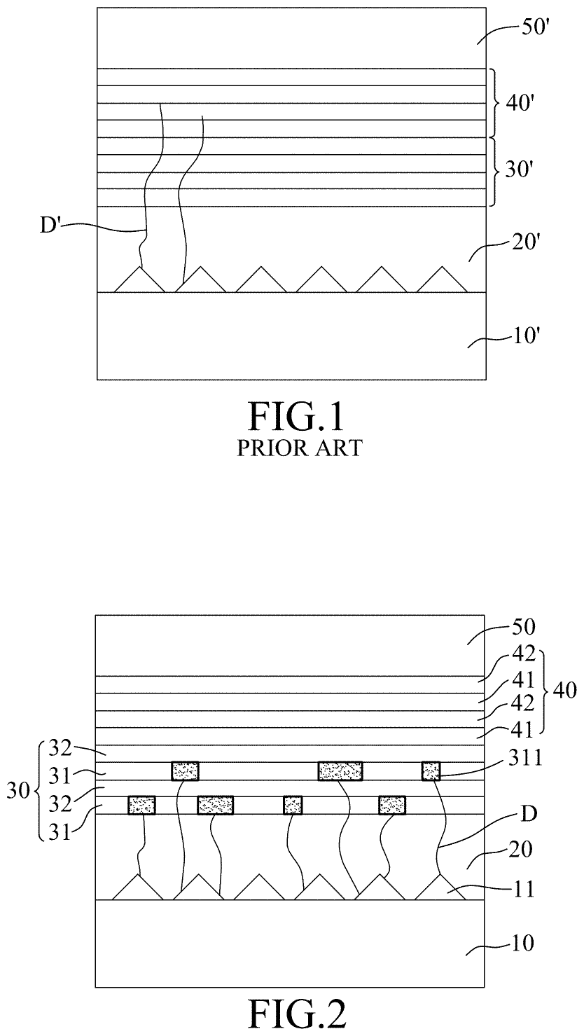

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Referring to FIG. 2, an embodiment of a light emitting diode (LED) according to the disclosure includes a substrate 10, a first conductivity-type semiconductor layer 20, a second conductivity-type semiconductor layer 50 which has a conductivity type opposite to that of the first conductivity-type semiconductor layer 20, a light emitting layer 40 disposed between the first conductivity-type semiconductor layer 20 and the second conductivity-type semiconductor layer 50, and a stress relief layer 30 disposed between the first conductivity-type semiconductor layer 20 and the light emitting layer 40, and including well layers 31 and barrier layers 32 stacked alternately. The stress relief layer 30 further includes at least one blocking zone 311 distributed in at least one of the well layers 31. The at least one blocking zone 311 has an energy gap greater than an energy gap of the at least one of the well layers 31.

The substrate 10 may be, for example, a sapphire substrate, a silicon carbide substrate, a silicon nitride substrate, or a silicon substrate. In addition, a surface of the substrate 10 may further be patterned so as to form a concave-convex structure 11 which may facilitate the output of light, thereby enhancing the light emission efficiency of the LED. However, the disclosure is not limited by the foregoing description. In certain embodiments, the substrate 10 is a patterned sapphire substrate, but the disclosure is not limited thereto.

The first conductivity-type semiconductor layer 20 may be a gallium nitride-based semiconductor layer which may be doped with n-type impurities for providing electrons. The second conductivity-type semiconductor layer 50 may be a gallium nitride-based semiconductor layer which may be doped with p-type impurities for providing holes. In addition, radiation recombination of electrons and holes may take place in the light emitting layer 40 so as to light up the LED. The stress relief layer 30 may be utilized for releasing stress in the LED. Each of the first conductivity-type semiconductor layer 20, the stress relief layer 30, the light emitting layer 40, and the second conductivity-type semiconductor layer 50 may be made of a material represented by a formula of AlₓIn_{y}Ga_{1-x-y}N, wherein 0≤x<1, 0≤y<1, and 0≤x+y<1.

In some embodiments, the well layers 31 are made of a material represented by a formula of Alₓ₁In_{y1}Ga_{1-x1-y1}N, and the at least one blocking zone 311 is made of a material represented by a formula of Alₓ₂In_{y2}Ga_{1-x2-y2}N, where 0≤x1<1, 0<y1<1, x1+y1<1, 0≤x2<1, 0≤y2<1, x2+y2<1, and y1>y2. In some embodiments, each of x1 and x2 is equal to 0.

When the first conductivity-type semiconductor layer 20 (e.g., the above-mentioned gallium nitride-based semiconductor layer) is deposited on the substrate 10 (e.g., a heterogeneous substrate, such as the sapphire substrate or the silicon carbide substrate), a great number of dislocations (D) may occur due to a lattice mismatch between the first conductivity-type semiconductor layer 20 and the substrate 10 which are made from different materials. Moreover, these dislocations (D) may extend along a direction of epitaxial growth in subsequent epitaxial growth processes. As these dislocations (D) arrive in the light emitting layer 40, non-radiative recombination of carriers tends to occur at sites of these dislocations (D), leading to a reduction of the light emission efficiency.

The light emitting layer 40 may include a single quantum well structure or a multi-quantum well structure. Japanese Invention Patent Application Publication No. 2001068733A discloses that an annealing treatment is performed on a typical quantum well structure under a hydrogen gas atmosphere so as to decompose InGaN crystalline which is located in sites of dislocations, thereby forming quantum boxes thereat. However, the above-mentioned treatment (i.e., annealing the quantum well structure under the hydrogen gas atmosphere so as to release indium from the sties of dislocations) may cause a blue shift of emission wavelength. In contrast to the quantum boxes in the quantum well structure, in this disclosure, the at least one blocking zone 311, which is similar to the foregoing quantum boxes, is disposed in at least one of the well layers 31 of the stress relief layer 30, rather than in the quantum well structure of the light emitting layer 40. Thus, in the LED of this disclosure, the occurrence of the blue shift may be avoided and non-radiative recombination may be eliminated or alleviated, thereby enhancing the light emission efficiency.

The light emitting layer 40 includes quantum well layers 41 and quantum barrier layers 42 stacked alternately. Each of the quantum barriers layers 42 has an energy gap greater than an energy gap of each of the quantum well layers 41. The light emitting layer 40 which may be made of the material represented by the formula of AlₓIn_{y}Ga_{1-x-y}N as described above, due to containing indium (In), is capable of emitting high-intensity light that has a wavelength falling within the blue wavelength range. In addition, the quantum well layers 41 may be nitride compound semiconductor layers containing indium, such as a material represented by a formula of Alₓ₃In_{y3}Ga_{1-x3-y3}N, wherein 0≤x3<1, 0<y3<1, x3+y3<1.

In some embodiments, x3 is equal to 0. Moreover, the quantum barrier layers 42 may be gallium nitride-based layers, such as a material represented by a formula of Alₓ₄In_{y4}Ga_{1-x4-y4}N, wherein 0≤x4≤1, 0≤y4≤1, x4+y4<1, and y4<y3. In an exemplary embodiment, the quantum barrier layers 42 are made of one of gallium nitride (GaN) and aluminum gallium nitride (AlGaN).

It should be noted that for the substrate 10, especially for the substrate 10 having a larger size, such as one having a diameter ranging from 4 to 12 inches, a higher temperature of epitaxial growth during epitaxial growth of lower layers (i.e., layers grown before the light emitting layer 40) may cause the lower layers to gradually become concave. If the light emitting layer 40 is grown right after the epitaxial growth of the lower layers, the following epitaxial layers may become convex. Therefore, stress may not be well released, and the epitaxial layers thus obtained may tend to exhibit greater warpage, which may result in cracking of the foregoing layers. Consequently, in this embodiment, the stress relief layer 30 is disposed between the first conductivity-type semiconductor layer 20 and the active layer 40 so as to allow the stress to be released and prevent cracking.

The stress relief layer 30 includes well layers 31 and barrier layers 32 stacked alternately. There exists a great number of dislocations (D) and defects in the well layers 31. The stress relief layer 30 is capable of releasing stress and reducing generation of the defects caused by the lattice mismatch between the substrate 10 (e.g., the sapphire substrate) and the first conductivity-type semiconductor layer 20 (e.g., the gallium nitride-based semiconductor layer). In an exemplary embodiment, the well layers 31 and the barrier layers 32 of the stress relief layer 30 are alternately and repeatedly stacked three times or more. In another exemplary embodiment, the well layers 31 and the barrier layers 32 are alternately and repeatedly stacked six times.

Since a great number of dislocations (D) are present in the well layers 31, the carriers in the stress relief layer 30 may migrate to sites of the dislocations (D) by lateral movement and may undergo non-radiative recombination thereat. In order to reduce the occurrence of non-radiative recombination, such lateral movement of the carriers to sites of the dislocations (D) shall be blocked. Accordingly, in this embodiment, by means of disposing the at least one blocking zone 311 at sites of these dislocations (D) in at least one of the well layers 31, such lateral movement may be blocked. Because the carriers usually migrate from a high-energy state to a low-energy state, the energy gap of the at least one blocking zone 311 needs to be greater than the energy gap of the at least one of well layers 31 so as to deter such lateral movement.

In certain embodiments, the stress relief layer 30 includes a plurality of the blocking zones 311. The dislocations (D) in the well layers 31 are randomly distributed, and the blocking zones 311 are mainly formed at sites of the dislocations (D). Therefore, the blocking zones 311 are randomly distributed in the well layers 31 as well. In some embodiments, the stress relief layer 30 includes a plurality of the blocking zones 311 which are evenly distributed. In some embodiments, after forming one of the well layers 31, the one of the well layers 31 is treated with a corrosive gas (e.g., hydrogen gas) so as to form recesses in the one of the well layers 31, and then one of the barrier layers 32 is grown on a surface of the one of the well layers 31 so as to fill the recesses with a material for growing the one of the barrier layers 32, thereby forming the blocking zones 311 in the recesses. By controlling a flow rate of the corrosive gas and positions from which the corrosive gas is introduced into a chamber or an apparatus for treating the one of the well layers 31, the one of the well layers 31 may be uniformly treated by an appropriate amount of corrosive gas within a certain time period, and thus the blocking zones 311 may be evenly distributed.

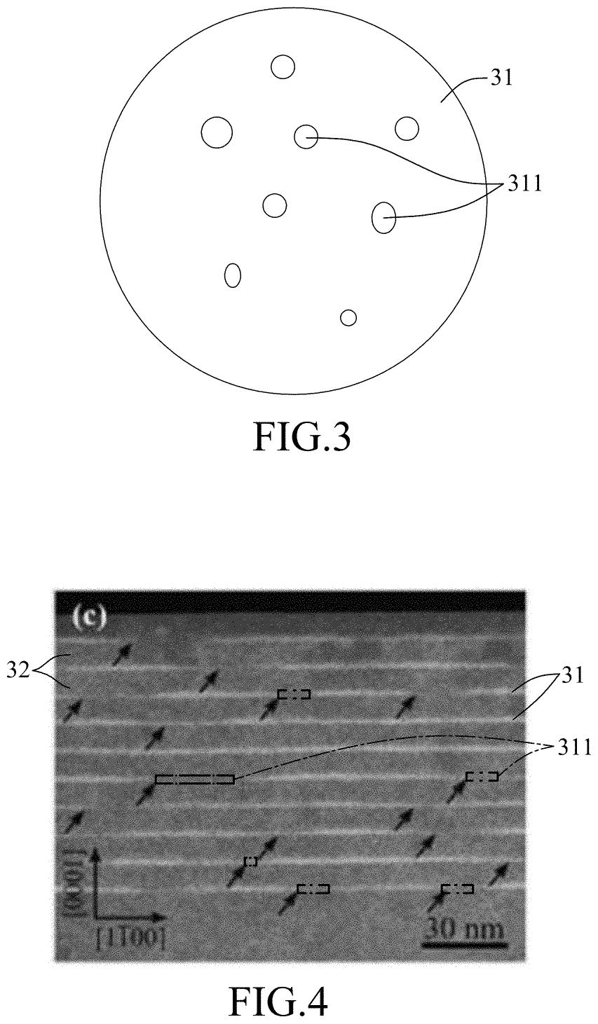

Referring to FIG. 3, the blocking zones 311 are randomly distributed in the well layers 31, and each of the blocking zones 311 is dot-shaped. In addition, the blocking zones 311 have a random size, and may have the same size or different sizes.

Referring to FIG. 4, the light area is the well layers 31, the dark area is the barrier layers 32, and the dark area indicated by arrows is the blocking zones 311.

It can be seen from afar of a cross-sectional transmission electron microscope (TEM) image shown in FIG. 4 that compared with the well layers 31 which are in a light color, the blocking zones 311 in stripe form are relatively darker. Taking a closer look at the image, it can be seen that each of the blocking zones 311 may have a section which is taken along a direction from the first conductivity-type semiconductor layer 20 to the second conductivity-type semiconductor layer 50, and which is in the form of an inverted triangular shape, a rectangular shape (including a square shape), or an irregular shape.

In some embodiments, the well layers 31 of the stress relief layer 30 may be indium-containing layers, and each of the blocking zones 311 may be an indium-free zone or an indium-containing zone. Moreover, a percentage of indium in each of the blocking zones 311 is less than a percentage of indium in a corresponding one of the well layers 31 so as to achieve the purpose of making each of the blocking zones 311 having the energy gap greater than the energy gap of the corresponding one of the well layers 31. A percentage of indium in each of the well layers 31 of the stress relief layer 30 is less than a percentage of indium in each of the quantum well layers 41 of the light emitting layer 40 which is a primary luminescent layer. Furthermore, an energy gap of each of the barrier layers 32 is greater than that of each of the well layers 31, and the energy gap of each of the blocking zones 311 is greater than that of each of the well layers 31. In certain embodiments, the energy gap of each of the blocking zones 311 is less than or equal to the energy gap of each of the barrier layers 32. In an exemplary embodiment, the energy gap of each of the blocking zones 311 is equal to that of each of the barrier layers 32. As mentioned above, the well layers 31 are made of a material represented by a formula of Alₓ₁In_{y1}Ga_{1-x1-y1}N, and the blocking zones 311 are made of a material represented by a formula of Alₓ₂In_{y2}Ga_{1-x2-y2}N, where 0≤x1<1, 0<y1<1, x1+y1<1, 0≤x2<1, 0≤y2<1, x2+y2<1, and y1>y2. In some embodiment, x1 is equal to 0. In some other embodiments, each of x1 and x2 is equal to 0. It is optimal to have a difference in energy gap between one of the blocking zones 311 and a corresponding one of the well layers 31 to the greatest extent possible. Therefore, in an exemplary embodiment, the blocking zones 311 are indium-free, thereby achieving a better blocking effect on the lateral movement of the carriers. In another exemplary embodiment, the well layers 31 are made of InGaN, the barrier layers 32 are made of GaN, and the blocking zones 311 are made of GaN, so that each of the blocking zones 311 and each of the barrier layers 32 have an energy gap that is equal and that is greater than the energy gap of each of the well layers 31.

Referring back to FIG. 2, in certain embodiments, each of the blocking zones 311 has an upper surface that is flush with an upper surface of a corresponding one of the well layers 31, and a lower surface that is in the corresponding one of the well layers 31 or that is flush with a lower surface of the corresponding one of the well layers 31 (as shown in FIGS. 2 and 4). That is to say, each of the well layers 31 may be in a continuous state of not actually being interrupted by its corresponding blocking zone(s) 311, or may be in a state of being interrupted by its corresponding blocking zone(s) 311. In an exemplary embodiment, each of the blocking zones 311 has a thickness that is less than or equal to a thickness of a corresponding one of the well layers 31. In another exemplary embodiment, each of the blocking zones 311 has an upper surface that is flush with an upper surface of a corresponding one of the well layers 31, and a lower surface that is in a corresponding one of the well layers 31, and a ratio of a thickness of each of the blocking zones 311 to a thickness of the corresponding one of the well layers 31 is less than or equal to ½, and is greater than 0. In yet another exemplary embodiment, each of the well layers 31 has a thickness that ranges from 10 Å to 50 Å, and each of the blocking zones 311 has a thickness not greater than 25 Å.

In other embodiments, each of the barrier layers 32 has a thickness that ranges from 30 Å to 200 Å. If a thickness of one of the barrier layers 32 is too small, it may be impossible to allow the one of the barrier layers 32 to have a flat upper surface, thus causing the blocking zones 311 (which are formed by filling the recesses in the one of the well layers 31 using the material for forming the one of the barrier layers 32) not to be fully filled so that the blocking effect may be poor. Nevertheless, if a thickness of one of the barrier layers 32 is too great, stress relieving may be limited. Therefore, in another exemplary embodiment, each of the barrier layers 32 has a thickness that ranges from 60 Å to 80 Å.

The disclosure provides a method for manufacturing the LED, comprising the following steps described below.

In step (a), the substrate 10, which may be a patterned sapphire substrate, is provided. After cleaning the substrate 10, the substrate 10 is moved to a metal organic chemical vapor deposition (MOCVD) apparatus for subsequent epitaxial depositing/growing.

Next, a MOCVD technique is adopted for depositing the first conductivity-type semiconductor layer 20 on the substrate 10. The first conductivity-type semiconductor layer 20 may be made of GaN doped with silicon (Si).

Afterward, the MOCVD technique is adopted again for depositing the stress relief layer 30 on the first conductivity-type semiconductor layer 20. The stress relief layer 30 includes well layers 31 and barrier layers 32 stacked alternately, the well layers 31 may be made of InGaN, and the barrier layers 32 may be made of GaN. The well layers 31 and the barrier layers 32 are grown alternately and repeatedly for six to eight times.

The stress relief layer 30 further includes at least one blocking zone 311 distributed in at least one of the well layers 31. In addition, the at least one blocking zone 311 has the energy gap greater than the energy gap of the at least one of the well layers 31. The at least one of the well layers 31 may be made of InGaN, and the at least one blocking zone 311 may be made of GaN.

In some embodiments, the at least one blocking zone 311 may be formed by using the following method. After growing the at least one of the well layers 31, a high-temperature treatment is carried out for treating the at least one of the well layers 31. Under a condition of such high temperature, materials in at least one part of dislocations (D) in the at least one of the well layers 31 become relatively unstable. As such, indium particularly, in the at least one part of dislocations (D) (which is located in a part of the at least one of the well layers 31) may be partially or fully removed during the high-temperature treatment, thereby obtaining the at least one blocking zone 311. For example, the indium removed from the part of the at least one of the well layers 31 may be moved into a remaining part of the at least one of the well layers 31, or be moved away from the at least one of the well layer 31. The at least one blocking zone 311 is an indium-free zone or an indium-containing zone having a percentage of indium less than a percentage of indium in the at least one of the well layers 31. When the at least one of the well layers 31 is made of InGaN, the at least one blocking zone 311 may be a GaN zone after indium therein being partially or fully removed. Moreover, in an exemplary embodiment, a temperature for treating the at least one of the well layers 31 is higher than a growth temperature of the at least one of the well layers 31 and is less than or equal to a growth temperature of the barrier layers 32. In another exemplary embodiment, the high temperature of treating the well layers 31 is performed under an ammonia gas atmosphere. The upper and lower surfaces of each of the well layers 31, and an upper surface and a lower surface of each of the barrier layers 32 may all be flat.

In still yet another embodiment, the temperature of treating the at least one of the well layers 31 ranges from 800° C. to 900° C. When the temperature is lower than 800° C., indium in InGaN (i.e., the material of the at least one of the well layers 31) may have a slow removal rate so that it takes a longer time period to perform the treatment. As the temperature exceeds 900° C.; however, indium in InGaN may have a very high removal rate, so that the time for the treatment is relatively short and may not be well controlled.

In other embodiments, the at least one blocking zone 311 may be formed by using another method described as follows. After growing the at least one of the well layers 31, a corrosion treatment is performed using a corrosive gas for treating a surface of the at least one of the well layers 31. In such circumstance, materials in at least one part of dislocations (D) in the at least one of the well layers 31 become relatively unstable, so that materials in the at least one part of the dislocations (D) are prone to be corroded by the corrosive gas and hence be removed so as to form recesses thereat. After that, one of the barrier layers 32 is grown on the surface of the at least one of the well layers 31 so that the recesses may be filled with the one of the barrier layers 32, thereby obtaining the at least one blocking zone 311. That is to say, the material of the at least one blocking zone 311 is the same with that of the one of the barrier layers 32. In an exemplary embodiment, the corrosive gas includes hydrogen gas. In this embodiment, the upper and lower surfaces of each of the well layers 31 and the barrier layers 32 may all be flat. In addition, the growth temperature of the well layers 31 is less than the growth temperature of the barrier layers 32. In another exemplary embodiment, a treating time of the corrosion treatment using hydrogen gas ranges from 10 seconds to 60 seconds at a flow rate ranging from 7 to 20 standard liter per minute (slm) under approximately 830° C.

However, if the well layers 41 of the light emitting layer 40 are treated with hydrogen gas, quantum wells of the quantum well layers 41 may be damaged, and luminescent areas of the quantum wells may decrease, consequently causing a reduction in light emission efficiency. In this embodiment, the corrosion treatment using hydrogen gas is carried out on the at least one of the well layers 31 of the stress relief layer 30. Since the well layers 30 are not provided for emitting light, the luminescent areas and light emission efficiency of the LED made by the method in this disclosure are less likely to be adversely affected.

Each of the high-temperature treatment and the corrosion treatment for forming the at least one blocking zone 311 may be performed in the MOCVD apparatus; therefore, it is not necessary to remove the substrate 10 for epitaxial depositing from the MOCVD apparatus for forming the at least one blocking zone 311 so as to facilitate the manufacturing process and mass production.

Furthermore, the MODCV technique is adopted for depositing the light emitting layer 40 on the stress relief layer 30. The light emitting layer 40 includes the quantum well layers 41 and the quantum barrier layers 42 stacked alternately. In an exemplary embodiment, the quantum well layers 41 are made of InGaN, and a percentage of indium in each of the quantum well layers 41 is greater than the percentage of indium in each of the well layers 31 of the stress relief layer 30. In another exemplary embodiment, the quantum barrier layers 42 are made of GaN. In yet another exemplary embodiment, the quantum well layers 41 and the quantum barrier layers 42 are grown alternately and repeatedly for six to eight times.

Afterward, the MOCVD technique is used once more for depositing the second conductivity-type semiconductor layer 50 on the light emitting layer 40. The second conductivity-type semiconductor layer 50 may be made of GaN doped with magnesium (Mg).

Subsequently, an etching technique is performed from the second conductivity-type semiconductor layer 50 to the first conductivity-type semiconductor layer 20 so as to expose a portion of the first conductivity-type semiconductor layer 20. After that, a first metal electrode is formed on a surface of the exposed portion of the first conductivity-type semiconductor layer 20, and meanwhile a second metal electrode is formed on a surface of the second conductivity-type semiconductor layer 50, thereby obtaining a semiconductor stack. Additionally, the etching technique may include a dry etching technique and a wet etching technique.

Lastly, the semiconductor stack thus obtained is subjected to a die-cutting operation so as to form chips, each of which may emit light independently. The die-cutting operation may include scribing, followed by cutting.

In this embodiment, each of the first conductivity-type semiconductor layer 20, the stress relief layer 30, the light emitting layer 40, and the second conductivity-type semiconductor layer 50 is a gallium nitride-based semiconductor layer. In addition, the depositing technique may be, for instance, a molecular beam epitaxy (MBE) technique, a MOCVD technique, or a hybrid vapor phase epitaxy (HVPE) technique; however, the disclosure is not limited thereto. In an exemplary embodiment, the MOCVD technique is used.

In sum, the disclosure provides the LED in which at least one blocking zone 311 is distributed in at least one of the well layers 31 of the stress relief layer 30 and is disposed at the dislocations (D) so as to block the lateral movement of the carriers, thereby preventing the non-radiative recombination of carriers at sites of the dislocations (D), which may cause a reduction in quantum efficiency of the LED. During the forming of the at least one blocking zone 311, the at least one of the well layers 31 is subjected to an annealing treatment under a nitrogen gas environment so as to sublime or remove indium in the part of the at least one of the well layers 31, thereby obtaining the at least one blocking zone 311. To be more specific, indium at sites of the dislocations (D) in the at least one of the well layers 31 is particularly easily to be partially or fully removed. Alternately, the at least one blocking zone 311 may be obtained by treating the at least one of the well layers 31 using the corrosion treatment under hydrogen gas so as to form recesses in the at least one of the well layers 31, followed by filling the recesses with a material having an energy gap higher than that of the at least one of the well layers 31.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light emitting diode (LED), comprising:
a first conductivity-type semiconductor layer and a second conductivity-type semiconductor layer which has a conductivity type opposite to that of said first conductivity-type semiconductor layer;
a light emitting layer disposed between said first conductivity-type semiconductor layer and said second conductivity-type semiconductor layer; and
a stress relief layer disposed between said first conductivity-type semiconductor layer and said light emitting layer, and including well layers and barrier layers stacked alternately,
wherein said stress relief layer further includes at least one blocking zone distributed in at least one of said well layers, said at least one blocking zone having an energy gap greater than an energy gap of said at least one of said well layers.

2. The LED as claimed in claim 1, wherein said stress relief layer includes a plurality of said blocking zones, said well layers having dislocations, at least part of said blocking zones being disposed at said dislocations.

3. The LED as claimed in claim 1, wherein the energy gap of said at least one blocking zone is less than or equal to an energy gap of each of said barrier layers.

4. The LED as claimed in claim 1, wherein said stress relief layer includes a plurality of said blocking zones which are evenly or randomly distributed in said well layers.

5. The LED as claimed in claim 1, wherein said stress relief layer includes a plurality of said blocking zones each of which is dot-shaped, said blocking zones being randomly distributed in said well layers.

6. The LED as claimed in claim 1, wherein said stress relief layer includes a plurality of said blocking zones each of which has
an upper surface flush with an upper surface of a corresponding one of said well layers, and
a lower surface that is in said corresponding one of said well layers or is flush with a lower surface of said corresponding one of said well layers.

7. The LED as claimed in claim 6, wherein each of said blocking zones has a thickness that is less than or equal to a thickness of said corresponding one of said well layers.

8. The LED as claimed in claim 7, wherein a ratio of the thickness of each of said blocking zones to the thickness of said corresponding one of said well layers is less than or equal to ½, and is greater than 0.

9. The LED as claimed in claim 1, wherein said well layers are indium-containing layers, and said at least one blocking zone is an indium-free zone or an indium-containing zone, a percentage of indium in said at least one blocking zone being less than a percentage of indium in said at least one of said well layers.

10. The LED as claimed in claim 9, wherein said well layers are made of a material represented by a formula of Alₓ₁In_{y1}Ga_{1-x1-y1}N, and said at least one blocking zone is made of a material represented by a formula of Alₓ₂In_{y2}Ga_{1-x2-y2}N, where x1=0, 0<y1<1, x2=0, 0≤y2<1, and y1>y2.

11. The LED as claimed in claim 10, wherein said well layers are made of InGaN, said barrier layers being made of GaN, said at least one blocking zone being made of GaN.

12. The LED as claimed in claim 1, wherein said at least one blocking zone has a section which is taken along a direction from said first conductivity-type semiconductor layer to said second conductivity-type semiconductor layer, and which is in a form of an inverted triangular shape, a rectangular shape, or an irregular shape.

13. A method for manufacturing an LED, comprising the steps of:
(a) providing a substrate;
(b) depositing a first conductivity-type semiconductor layer on the substrate;
(c) depositing a stress relief layer on the first conductivity-type semiconductor layer, the stress relief layer including well layers and barrier layers stacked alternately;
(d) depositing a light emitting layer on the stress relief layer; and
(e) depositing a second conductivity-type semiconductor layer on the light emitting layer,
wherein the stress relief layer further includes at least one blocking zone formed in at least one of the well layers, an energy gap of the at least one blocking zone being greater than an energy gap of the at least one of the well layers.

14. The method as claimed in claim 13, wherein the at least one blocking zone is formed by treating the at least one of the well layers using a high-temperature treatment so as to permit indium in at least one part of dislocations in the at least one of well layers to partially or fully removed, thereby forming the at least one blocking zone.

15. The method as claimed in claim 14, wherein a temperature for treating the at least one of the well layers is higher than a growth temperature of the at least one of the well layers and is less than or equal to a growth temperature of the barrier layers.

16. The method as claimed in claim 15, wherein the high-temperature treatment for treating the well layers is performed under an ammonia gas atmosphere.

17. The method as claimed in claim 13, wherein the at least one blocking zone is formed by:
treating the at least one of the well layers using a corrosive gas so as to form at least one recess in at least one dislocations in the at least one of the well layers; and
growing one of the barrier layers on a surface of the at least one of the well layers such that the at least one recess is filled with a material for growing the one of the barrier layers, thereby forming the at least one blocking zone in the at least one recess.

18. The method as claimed in claim 17, wherein the corrosive gas includes hydrogen gas.
